(19) United States
(12) Patent Application Publication
(10) Pub. No.: US 2026/0293713 A1
(43) Pub. Date: Sep. 24, 2026

(54) SEMICONDUCTOR PACKAGE AND METHOD OF MANUFACTURING THE SAME

(71) Applicant: SAMSUNG ELECTRONICS CO., LTD., SUWON-SI (KR)

(72) Inventor: Minyan Wu, Suzhou Industrial Park (CN)

(21) Appl. No.: 19/171,565

(22) Filed: Apr. 7, 2025

(30) Foreign Application Priority Data
Mar. 21, 2025 (CN) 202510339201.2

(51) Int. Cl. H01L 23/538; H01L 23/00; H01L 23/31; H01L 25/07

(52) U.S. Cl. CPC H10W 70/611; H10W 70/614; H10W 70/65; H10W 90/00; H10W 90/401; H10W 72/877; H10W 74/111; H10W 90/724; H10W 90/734

(57) ABSTRACT

A semiconductor package including: a substrate; a first unit structure and a second unit structure on the substrate; a molding layer covering the first and second unit structures; and a conductive via within the molding layer and electrically connected to the substrate, wherein each of the first and second unit structures includes: an interposer layer; a lower unit chip; an upper unit chip; a lower redistribution layer; an upper redistribution layer, wherein each of the lower and upper unit chips has an active surface facing the interposer layer and a passive surface opposite to its active surface, and wherein the passive surface of the upper unit chip of the first unit structure and the passive surface of the lower unit chip of the second unit structure face each other.

### CROSS-REFERENCE TO RELATED APPLICATIONS

This U.S. patent application claims priority under 35 U.S.C. § 119 to Chinese Patent Application No. 202510339201.2 filed on Mar. 21, 2025, in the Chinese National Intellectual Property Administration, the disclosure of which is incorporated by reference in its entirety herein.

### TECHNICAL FIELD

The present disclosure relates to a semiconductor package and a method of manufacturing the same, and more particularly, to a semiconductor package with a reduced thickness and a method of manufacturing the same.

### DESCRIPTION OF THE RELATED ART

With the continuous advancement of electronic industry, there is a growing demand for high performance, faster response speeds and miniaturized electronic components. To meet this demand, semiconductor packaging technologies have evolved, including packages where a plurality of semiconductor chips are stacked on a single package substrate and package on package (POP) structures where multiple packages are stacked.

For example, a semiconductor package may include a plurality of stacked semiconductor chips, which are electrically connected to a substrate through a wire bonding process. However, to prevent wire exposure or damage to the wires and chips during laser processing, the wire bonding process requires additional space within the package. This spatial requirement can result in an increased package thickness.

Although Through Silicon Via (TSV) technology can help reduce package thickness to some extent, its manufacturing process is complex and prone to defects, which can negatively impact the overall reliability of the package.

### SUMMARY

An example embodiment of the present disclosure provides a semiconductor package with reduced thickness and enhanced reliability, along with a method for its manufacturing.

An example embodiment of the present disclosure provides a semiconductor package including: a substrate; a first unit structure and a second unit structure sequentially stacked on the substrate; a molding layer on the substrate and covering the first unit structure and the second unit structure; and a conductive via within the molding layer and electrically connected to the substrate, wherein each of the first unit structure and the second unit structure includes: an interposer layer; a lower unit chip below the interposer layer; an upper unit chip above the interposer layer; a lower redistribution layer between the lower unit chip and the interposer layer and electrically connected to the interposer layer, the lower unit chip, and the conductive via; an upper redistribution layer between the upper unit chip and the interposer layer and electrically connected to the interposer layer, the upper unit chip and the conductive via, wherein each of the lower unit chip and the upper unit chip has an active surface facing the interposer layer and a passive surface opposite to its active surface, and wherein the passive surface of the upper unit chip of the first unit structure and the passive surface of the lower unit chip of the second unit structure face each other.

An example embodiment of the present disclosure provides a semiconductor package including: a substrate; a first chip in a groove of the substrate; a first unit structure above the first chip; a second unit structure above the first unit structure; a molding layer on the substrate and covering the first unit structure and the second unit structure; and a conductive via within the molding layer and electrically connected to the substrate, wherein each of the first unit structure and the second unit structure includes: a lower unit chip and an upper unit chip each including an active surface and a passive surface opposite to its active surface; a conductive bump between the lower unit chip and the upper unit chip and directly connected to one of the lower unit chip and the upper unit chip; and a redistribution layer between the lower unit chip and the upper unit chip and directly connected to the conductive bump and conductive via and the other one of the lower unit chip and the upper unit chip, wherein in each of the lower unit chip and the upper unit chip, the active surface of the lower unit chip and the active surface of the upper unit chip face each other, and wherein the passive surface of the upper unit chip of the first unit structure and the passive surface of the lower unit chip of the second unit structure face each other.

An example embodiment of the present disclosure provides a method of manufacturing a semiconductor package, the method including: preparing a first unit structure and a second unit structure, wherein each of the first unit structure and the second unit structure comprises: an interposer layer; a lower unit chip below the interposer layer; an upper unit chip above the interposer layer; a lower redistribution layer between the lower unit chip and the interposer layer and electrically connected to the interposer layer, the lower unit chip, and the conductive via; and an upper redistribution layer between the upper unit chip and the interposer layer and electrically connected to the interposer layer, the upper unit chip and the conductive via, wherein each of the lower unit chip and the upper unit chip has an active surface facing the interposer layer and a passive surface opposite to its active surface; disposing the first unit structure on a substrate; disposing the second unit structure on the first unit structure such that the passive surface of the upper unit chip of the first unit structure and the passive surface of the lower unit chip of the second unit structure face each other; and forming a molding layer covering the first unit structure and the second unit structure on the substrate and forming a conductive via within the molding layer and electrically connecting the conductive via to the substrate.

An example embodiment of the present disclosure provides a method of manufacturing a semiconductor package, the method including: preparing a first unit structure and a second unit structure, wherein each of the first unit structure and the second unit structure comprises: a lower unit chip and an upper unit chip each comprising an active surface and a passive surface opposite to its active surface; a conductive bump between the lower unit chip and the upper unit chip and directly connected to one of the lower unit chip and the upper unit chip; and a redistribution layer between the lower unit chip and the upper unit chip and directly connected to the conductive bump and conductive via and the other one of the lower unit chip and the upper unit chip; disposing the first chip within a groove of the substrate; disposing the first unit structure on the first chip; disposing the second unit structure on the first unit structure such that a passive surface of the upper unit chip of the first unit structure and a passive surface of the lower unit chip of the second unit structure face each other; and forming a molding layer covering the first unit structure and the second unit structure on the substrate and forming a conductive via within the molding layer to be electrically connected to the substrate.

### BRIEF DESCRIPTION OF THE DRAWINGS

The above and other features of the present disclosure will become apparent through a detailed description of some example embodiments, provided in conjunction with the accompanying drawings. In the drawings, like reference numerals denote like elements throughout. In the drawings:

FIG. 1 is a cross-sectional view illustrating a semiconductor package according to a first example embodiment of the present disclosure;

FIGS. 2, 3, 4, 5, 6 and 7 are cross-sectional views illustrating intermediate steps of a method of manufacturing the semiconductor package according to the first example embodiment of the present disclosure;

FIGS. 8, 9 and 10 are cross-sectional views illustrating intermediate steps of another method of manufacturing the semiconductor package according to the first example embodiment of the present disclosure;

FIG. 11 is a cross-sectional view illustrating a semiconductor package according to a second example embodiment of the present disclosure;

FIGS. 12, 13, 14, 15, 16, 17, 18, 19, 20 and 21 are cross-sectional views illustrating intermediate steps of a method of manufacturing the semiconductor package according to the second example embodiment of the present disclosure;

FIG. 22 is a cross-sectional view illustrating a semiconductor package according to a third example embodiment of the present disclosure; and

FIGS. 23, 24, 25, 26 and 27 are cross-sectional views illustrating intermediate steps of a method of manufacturing the semiconductor package according to the third example embodiment of the present disclosure.

### DETAILED DESCRIPTION OF THE EMBODIMENTS

Various example embodiments of the present disclosure will now be described in detail with reference to the drawings. However, the present disclosure may take various forms and should not be limited to the specific embodiments described herein. Rather, these embodiments are provided to ensure a thorough and complete understanding of the disclosure and to fully convey its scope to those skilled in the art. For clarity, the sizes of layers and regions in the drawings may be exaggerated.

Certain details may be omitted in the drawings for convenience of illustration. Therefore, the accompanying drawings should not be interpreted as limiting the scope of the present disclosure in any way.

Spatially relative terms, such as “under,” “below,” “beneath,” “lower,” “on,” “above,” “over,” “upper,” and similar terms are used for descriptive convenience to indicate the relationship between elements or features as illustrated in the figures. These terms are intended to encompass different orientations of the device in use or operation, beyond the orientation depicted in the figures. For example, if the device in the figures is turned over, elements described as “below” or “beneath” other elements may instead be oriented “above” the other elements. Similarly, the term “below” can refer to both “above” and “below” depending on orientation. The device may also be positioned at different angles (e.g., rotated 90 degrees or orientations), and the spatial descriptors should be interpreted accordingly.

It will be understood that when an element such as a layer, film, region, area, or substrate is referred to as being “on” or “above” another element, the element may be directly on the other element, or an intervening element may also be present. When an element is referred to as “directly on” another element, there is no intervening element. In addition, in the present specification, the words “on” or “above” may refer to being positioned either above or below the target portion and do not necessarily indicate placement on the upper side of the target portion relative to the direction of gravity.

Although the term “same,” “equal” or “identical” are used in description of example embodiments, it should be understood that minor variations may exist. Thus, when one element is described as being the same as another, it should be interpreted as meaning that the element or value is the same within an acceptable manufacturing or operational tolerance range (e.g., ±10%).

When the terms “about” or “substantially” are used in this specification in connection with a numerical value, they indicate that the stated value includes a manufacturing or operational tolerance (e.g., ±10%). Moreover, when the terms “about” and “substantially” are used in connection with geometric shapes, they imply that absolute precision is not required, allowing for reasonable variations within the scope of the disclosure. In addition, regardless of whether numerical values or shapes are modified as “about” or “substantially,” they should be construed as including a manufacturing or operational tolerance (e.g., ±10%) around the stated numerical values or shapes.

Hereinafter, a semiconductor package according to an example embodiment of the present disclosure and a manufacturing method thereof will be described.

This disclosure relates to a semiconductor package and its manufacturing method, designed to reduce package thickness while improving reliability and electrical performance. The package features stacked unit structures, each comprising an interposer layer, lower unit chip, upper unit chip, and redistribution layers for electrical connectivity. Instead of traditional wire bonding or through-silicon vias (TSVs), the disclosure uses conductive vias within a molding layer to establish electrical connections, simplifying manufacturing and enhancing yield. Additionally, the passive surfaces of adjacent unit structures are bonded together, creating a compact and stable stack that maintains electrical integrity.

By leveraging thin chips and adhesive layers for structural stability, the design significantly reduces overall package height while improving mechanical strength and reliability. Some embodiments incorporate a base chip (e.g., a system-on-chip (SoC)) directly on or within the substrate, further minimizing thickness. The scalability of this approach allows for additional stacked unit structures, making it ideal for high-performance memory devices, SoC applications, and advanced computing solutions. This innovation ensures higher bandwidth, improved electrical performance, and better manufacturability compared to conventional semiconductor packaging techniques.

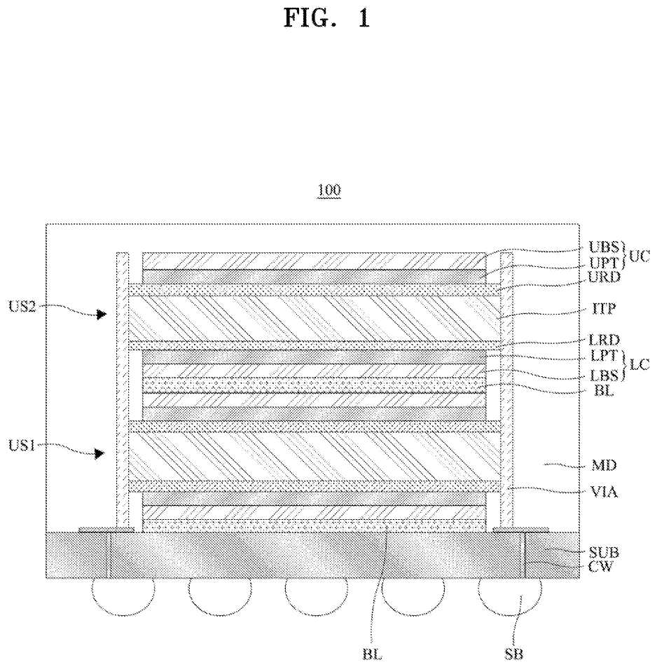

FIG. 1 is a cross-sectional view illustrating a semiconductor package 100 according to a first example embodiment of the present disclosure.

Referring to FIG. 1, the semiconductor package 100 according to the first example embodiment of the present disclosure includes a substrate SUB, a first unit structure US1, a second unit structure US2, a molding layer MD, and a conductive via VIA.

The substrate SUB may be any substrate commonly used for manufacturing a semiconductor package. In an example embodiment, the substrate SUB may be formed of an insulating material such as quartz, glass, silicon nitride, silicon oxynitride, and organic resin. In an example embodiment, the substrate SUB may be formed of a semiconductor material. For example, the substrate SUB may be a silicon substrate or may include other materials such as silicon germanium, silicon germanium on insulator (SGOI), indium antimonide, lead telluride, indium arsenide, indium phosphide, gallium arsenide, or gallium antimonide.

The substrate SUB may have a conductive path CW. For example, the conductive path CW may include pads provided on a top surface of the substrate SUB, and wirings, and vias, and the like provided inside the substrate SUB.

The first unit structure US1 and the second unit structure US2 may be sequentially stacked on the substrate SUB. As shown in FIG. 1, the first unit structure US1 may be provided on the substrate SUB, and the second unit structure US2 may be provided on the first unit structure US1. For example, the first unit structure US1 may be bonded to the top surface of the substrate SUB by an adhesive layer BL.

Each of the first unit structure US1 and the second unit structure US2 may be a chip structure having a double-sided pattern, and the chip structure having a double-sided pattern may include an interposer layer and unit chips on both sides of the interposer layer. For example, as illustrated in FIG. 1, each of the first unit structure US1 and the second unit structure US2 may include an interposer layer ITP, a lower redistribution layer LRD and an upper redistribution layer URD located on both sides of the interposer layer ITP. Additionally, each of the first unit structure US1 and the second unit structure US2 may include a lower unit chip LC and an upper unit chip UC located on both sides of the interposer layer ITP.

Specifically, as shown in FIG. 1, the lower redistribution layer LRD may be located below the interposer layer ITP, and the lower unit chip LC may be located below the lower redistribution layer LRD; and the upper redistribution layer URD may be located above the interposer layer ITP, and the upper unit chip UC may be located above the upper redistribution layer URD. In other words, the lower unit chip LC and the upper unit chip UC may be located on a lower surface and an upper surface of the interposer layer ITP, respectively, the lower redistribution layer LRD may be located between the lower surface of the interposer layer ITP and the lower unit chip LC, and the upper redistribution layer URD may be located between the upper surface of the interposer layer ITP and the upper unit chip UC.

The interposer layer ITP may be a silicon interposer layer. A conductive path including pads, vias, wirings, etc. may be provided in the interposer layer ITP so that elements located on both sides of the interposer layer ITP can transmit information to each other.

The lower redistribution layer LRD and the upper redistribution layer URD may be provided between the lower unit chip LC and the interposer layer ITP and between the upper unit chip UC and the interposer layer ITP, respectively. Each of the lower redistribution layer LRD and the upper redistribution layer URD may include pads, vias, wirings, and insulating layers. The lower redistribution layer LRD and the upper redistribution layer URD may be electrically connected to wirings inside the interposer layer ITP.

The lower unit chip LC and the upper unit chip UC may be chips having a relatively thin thickness. For example, thicknesses of the upper unit chip UC and the lower unit chip LC may be 25 μm or less.

Each of the lower unit chip LC and the upper unit chip UC may have an active surface facing the interposer layer ITP and a passive surface opposite to the active surface. As shown in FIG. 1, the passive surface of the upper unit chip UC of the first unit structure US1 and the passive surface of the lower unit chip LC of the second unit structure US2 may face each other and be bonded to each other by an adhesive layer BL.

Each of the lower unit chip LC and the upper unit chip UC may include a base layer and a pattern layer. For example, as shown in FIG. 1, the lower unit chip LC may include a lower base layer LBS and a lower pattern layer LPT, and the upper unit chip UC may include an upper base layer UBS and an upper pattern layer UPT. In the lower unit chip LC, the lower base layer LBS may be located below the lower pattern layer LPT, and in the upper unit chip UC, the upper base layer UBS may be located above the upper pattern layer UPT.

The lower pattern layer LPT and the upper pattern layer UPT may be located on opposite surfaces of the interposer layer ITP. In other words, the lower pattern layer LPT and the upper pattern layer UPT may be located on the lower redistribution layer LRD and the upper redistribution layer URD, respectively. For example, as shown in FIG. 1, the lower pattern layer LPT is located below the lower redistribution layer LRD, and the lower redistribution layer LRD is located between the lower pattern layer LPT and the interposer layer ITP. The upper pattern layer UPT is located above the upper redistribution layer URD, and the upper redistribution layer URD is located between the upper pattern layer UPT and the interposer layer ITP.

The lower pattern layer LPT may be electrically connected to the lower redistribution layer LRD, and the upper pattern layer UPT may be electrically connected to the upper redistribution layer URD. For example, the lower pattern layer LPT may make direct contact with the lower redistribution layer LRD, and the upper pattern layer UPT may make direct contact with the upper redistribution layer URD. Therefore, the lower unit chip LC may be electrically connected to the lower redistribution layer LRD through the lower pattern layer LPT, and then electrically connected to the interposer layer ITP. The upper unit chip UC may be electrically connected to the upper redistribution layer URD through the upper pattern layer UPT, and then electrically connected to the interposer layer ITP. As a result, the lower unit chip LC and the upper unit chip UC can be electrically connected to each other via the lower redistribution layer LRD, the interposer layer ITP, and the upper redistribution layer URD enabling mutual information transmission.

Each of the lower pattern layer LPT and the upper pattern layer UPT may include elements such as transistors, capacitors, resistors, and the like, and insulating layers covering these elements.

The lower base layer LBS and the upper base layer UBS may be located on opposite surfaces of the interposer layer ITP. In other words, the lower base layer LBS and the upper base layer UBS may be located on the lower pattern layer LPT and the upper pattern layer UPT, respectively. For example, as shown in FIG. 1, the lower base layer LBS is located below the lower pattern layer LPT, and the lower pattern layer LPT is located between the lower base layer LBS and the lower redistribution layer LRD. The upper base layer UBS is located above the upper pattern layer UPT, and the upper pattern layer UPT is located between the upper base layer UBS and the upper redistribution layer URD.

The lower base layer LBS and the upper base layer UBS may be substrates for forming the lower pattern layer LPT and the upper pattern layer UPT, respectively. Each of the lower base layer LBS and the upper base layer UBS may be formed of a semiconductor material. For example, each of the lower base layer LBS and the upper base layer UBS may be a silicon substrate, or may include other materials such as silicon germanium, silicon germanium on insulator (SGOI), indium antimonide, lead telluride, indium arsenide, indium phosphide, gallium arsenide, or gallium antimonide.

As described above, the first unit structure US1 and the second unit structure US2 may be configured as a double-sided pattern chip structure including an interposer layer with redistribution layers and unit chips symmetrically disposed on both sides of the interposer layer. Each of the first unit structure US1 and the second unit structure US2 may be or include a dynamic random access memory (DRAM) chip or a system-on-chip (SoC) chip.

The molding layer MD may be provided on the substrate SUB and cover the first unit structure US1 and the second unit structure US2. The molding layer MD may include or be formed of an epoxy molding compound (EMC).

The conductive via VIA may be disposed within the molding layer MD. For example, the conductive via VIA may penetrate a portion of the molding layer MD and extend to the top surface of the substrate SUB. The conductive via VIA may be electrically connected to the conductive path CW of the substrate SUB. For example, the conductive via VIA may make direct contact with the conductive path CW. In addition, the conductive via VIA may be electrically connected to the lower redistribution layer LRD and the upper redistribution layer URD of each of the first unit structure US1 and the second unit structure US2. For example, the conductive via VIA may make direct contact with the lower redistribution layer LRD and the upper redistribution layer URD. Therefore, each of the first unit structure US1 and the second unit structure US2 may be electrically connected to the conductive path CW in the substrate SUB through the lower redistribution layer LRD and the upper redistribution layer URD and the conductive via VIA.

As shown in FIG. 1, side surfaces of the lower redistribution layer LRD and the upper redistribution layer URD may contact the conductive vias VIA, and the widths of the lower redistribution layer LRD and the upper redistribution layer URD may each be equal to a distance between the two conductive vias VIA. The side surfaces of the interposer layer ITP may also contact the conductive vias VIA, and the width of the interposer layer ITP may also be equal to the distance between the two conductive vias VIA. Side surfaces of the lower pattern layer LPT and the upper pattern layer UPT and the side surfaces of the lower base layer LBS and the upper base layer UBS may be spaced apart from the conductive vias VIA. In this case, gaps may be formed between the conductive vias VIA and the side surfaces of the lower pattern layer LPT and the upper pattern layer UPT and the side surfaces of the lower base layer LBS and the upper base layer UBS. The widths of the lower pattern layer LPT and the upper pattern layer UPT and the widths of the lower base layer LBS and the upper base layer UBS may be smaller than the distance between the two conductive vias VIA.

In an example embodiment, the interposer layer ITP may have a first width, the lower redistribution layer LRD and the upper redistribution layer URD may have a second width, the lower pattern layer LPT and the upper pattern layer UPT may have a third width, and the lower base layer LBS and the upper base layer UBS may have a fourth width. The first width may be equal to the second width, the third width may be equal to the fourth width, and the first and second widths may be greater than the third and fourth widths.

In addition, as illustrated in FIG. 1, the semiconductor package 100 may further include solder balls SB provided on a bottom surface of the substrate SUB. The solder balls SB may be used as a connection terminal for connecting the semiconductor package 100 to an external device. The solder balls SB may be electrically connected to the conductive path CW in the substrate SUB. For example, the solder balls SB may make direct contact with the conductive path CW. Therefore, each of the first unit structure US1 and the second unit structure US2 can be electrically connected to the external device by the solder balls SB.

Although the semiconductor package 100 is illustrated in FIG. 1 as including only two unit structures, the present disclosure is not limited thereto. The semiconductor package 100 may include one or more additional unit structures stacked on the second unit structure US2, each having substantially the same structure as the first unit structure US1 and the second unit structure US2.

The semiconductor package 100 according to the first example embodiment of the present disclosure includes unit structures configured as a double-sided pattern chip structure, resulting in reduced thickness and enhanced reliability. For example, the semiconductor package 100 may be manufactured without using a wire bonding process or a through silicon via process, thereby minimizing thickness, improving reliability, and enhancing electrical performance, such as increased bandwidth.

Hereinafter, a method of manufacturing the semiconductor package 100 of the first example embodiment according to an embodiment of the present disclosure will be described.

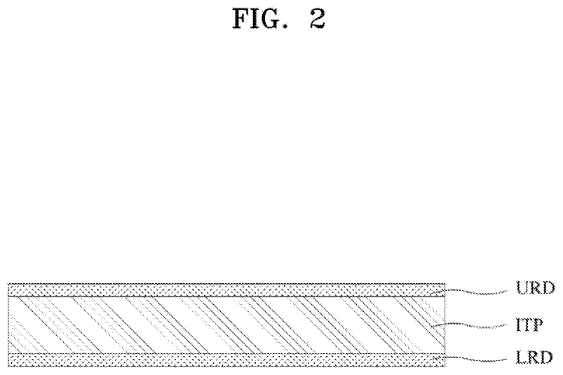

FIGS. 2 to 7 are cross-sectional views illustrating intermediate steps of a method of manufacturing the semiconductor package 100 according to the first example embodiment of the present disclosure.

Referring to FIG. 2, a lower redistribution layer LRD and an upper redistribution layer URD may be formed on a lower surface and an upper surface of the interposer layer ITP, respectively. For example, the lower redistribution layer LRD and the upper redistribution layer URD may face each other.

For example, the lower redistribution layer LRD may be formed on the lower surface of the interposer layer ITP first, and then, the upper redistribution layer URD may be formed on the upper surface of the interposer layer ITP, but the present disclosure is not limited thereto. For example, the upper redistribution layer URD may be formed on the upper surface of the interposer layer ITP first, and then, the lower redistribution layer LRD may be formed on the lower surface of the interposer layer ITP.

For example, the lower redistribution layer LRD and the upper redistribution layer URD may be formed by first depositing a metal layer on the surface of the interposer layer ITP, followed by patterning the metal layer through an etching process to create metal wiring. An insulating layer is then deposited to cover the metal wiring, after which a via is formed within the insulating layer to establish an electrical connection with the metal wiring. Finally, a pad electrically connected to the via is formed on the surface of the insulating layer. The lower redistribution layer LRD and the upper redistribution layer URD may include a single-layer structure or a multi-layer structure.

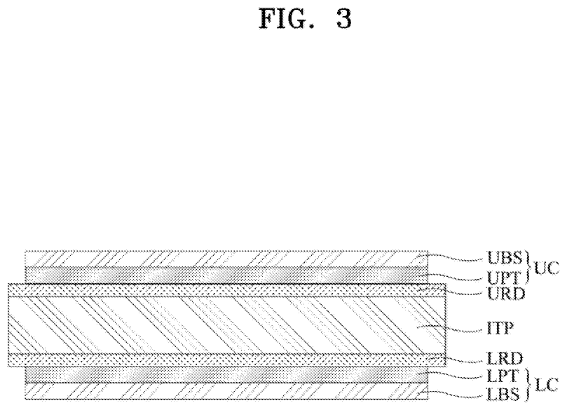

Referring to FIG. 3, the lower unit chip LC and the upper unit chip UC may be attached to the lower redistribution layer LRD and the upper redistribution layer URD, respectively, to obtain one unit structure (for example, the first unit structure US1). The process may be repeated to obtain another unit structure (e.g., the second unit structure US2).

For example, a lower pattern layer LPT of the lower unit chip LC and an upper pattern layer UPT of the upper unit chip UC may be attached to pads of the lower redistribution layer LRD and pads of the upper redistribution layer URD, respectively. This arrangement ensures that the lower pattern layer LPT (or active surface) of the lower unit chip LC and the upper pattern layer UPT (or active surface) of the upper unit chip UC face the interposer layer ITP, and a passive surface of the lower unit chip LC and a passive surface of the upper unit chip UC face away from the interposer layer ITP.

For example, the attachment may be achieved through a metal bonding process, such as Cu-to-Cu boding, or by a thermos-ultrasonic process. However, the present disclosure is not limited thereto.

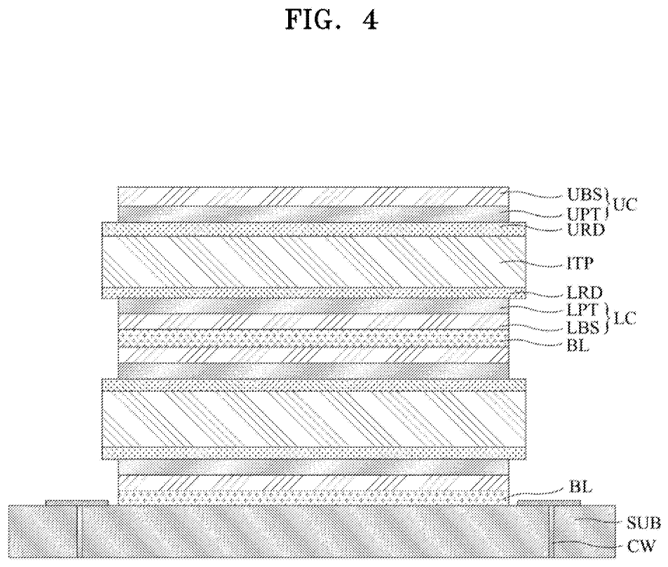

Referring to FIG. 4, the first unit structure US1 and the second unit structure US2 may be sequentially stacked on the substrate SUB.

For example, the first unit structure US1 may be attached to the substrate SUB by an adhesive layer BL, and the second unit structure US2 may be attached to the first unit structure US1 by an adhesive layer BL.

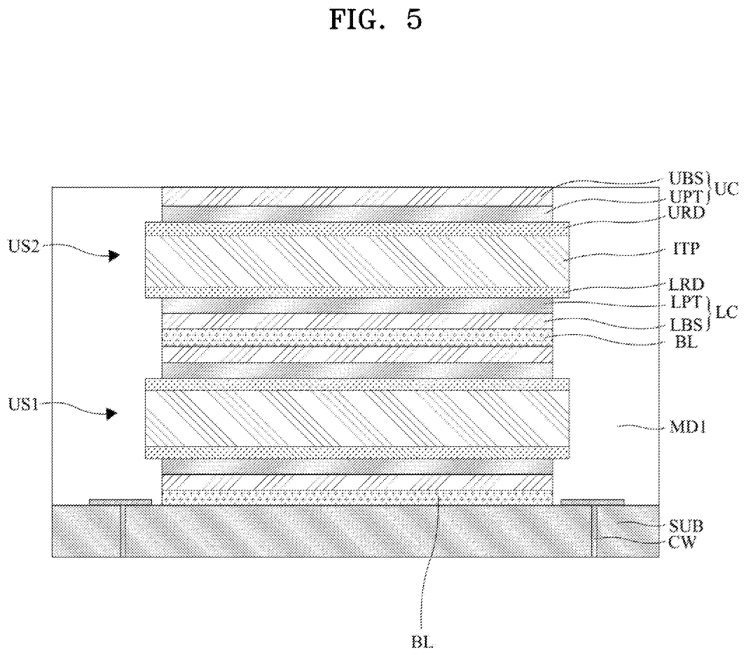

Referring to FIG. 5, a first sub-molding layer MD1 may be formed on the substrate SUB.

For example, a preliminary first sub-molding layer covering the first unit structure US1 and the second unit structure US2 may be first formed on the substrate SUB. Then, a planarization process may be performed on the preliminary first sub-molding layer to obtain the first sub-molding layer MD1. The first sub-molding layer MD1 may include or be formed of an epoxy molding compound (EMC). As shown in FIG. 5, a top surface of the first sub-molding layer MD1 may be substantially coplanar with the passive surface of the upper unit chip UC of the second unit structure US2. In other words, the top of the first sub-molding layer MD1 may be substantially coplanar with the top surface of the upper base layer UBS of the second unit structure US2. However, the present disclosure is not limited thereto, and the top surface of the first sub-molding layer MD1 may be higher than the passive surface of the upper unit chip UC of the second unit structure US2. For example, the distance from the top surface of the first sub-molding layer MD1 to the top surface of the substrate SUB may be equal to or greater than the distance from the passive surface of the upper unit chip UC of the second unit structure US2 to the top surface of the substrate SUB. In other words, the distance from the top surface of the first sub-molding layer MD1 to the top surface of the substrate SUB may be equal to or greater than the distance from the top surface of the upper base layer UBS of the second unit structure US2 to the top surface of the substrate SUB.

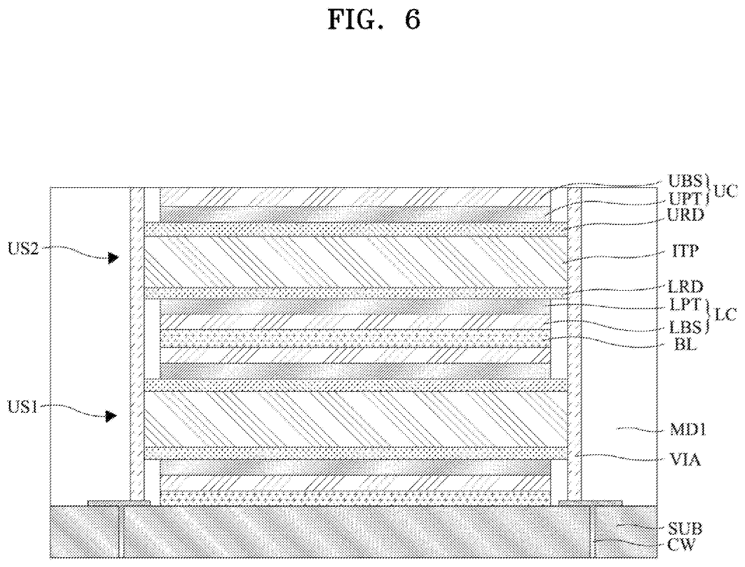

Referring to FIG. 6, conductive vias VIA penetrating the first sub-molding layer MD1 may be formed.

For example, a drilling process may first be performed on the first sub-molding layer MD1 to create a through hole that penetrates the first sub-molding layer MD1. This through hole may expose side surfaces of the interposer layer ITP, as well as the lower redistribution layer LRD and the upper redistribution layer URD of each of the first unit structure US1 and the second unit structure US2. An electroplating process may then be performed within the through hole to form the conductive via VIA.

The conductive via VIA may be electrically connected to the conductive path CW of the substrate SUB and may also establish electrical connections with the lower redistribution layer LRD and the upper redistribution layer URD of each of the first unit structure US1 and the second unit structure US2.

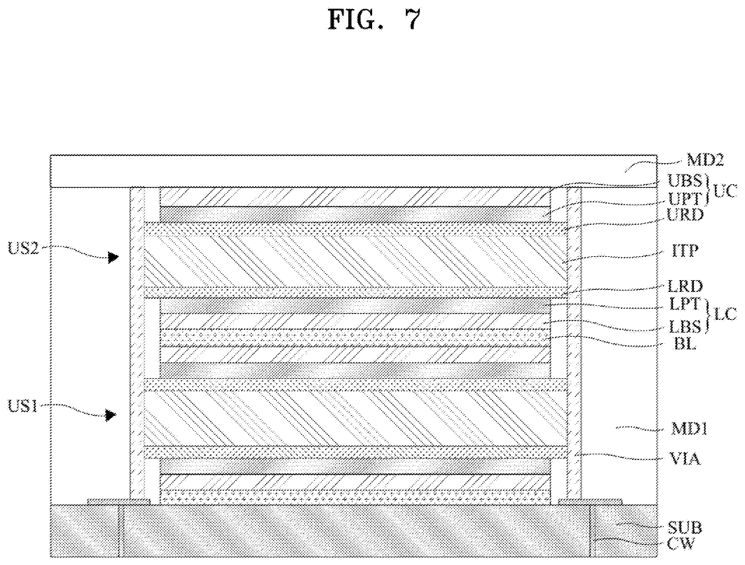

Referring to FIG. 7, a second sub-molding layer MD2 covering the first sub-molding layer MD1, the conductive via VIA, and the passive surface of the upper unit chip UC of the second unit structure US2 may be formed. The second sub-molding layer MD2 may be formed by substantially the same process as the process of forming the first sub-molding layer MD1. The second sub-molding layer MD2 may include or be formed of an epoxy molding compound (EMC). A thickness of the second sub-molding layer MD2 may be referred to as a mold gap. The second sub-molding layer MD2 may have a relatively small thickness, helping to reduce the overall thickness of the semiconductor package 100 compared to a package formed using a wire bonding process.

The second sub-molding layer MD2 may include the same material as the first sub-molding layer MD1. The first sub-molding layer MD1 and the second sub-molding layer MD2 may constitute the molding layer MD.

Next, referring to FIG. 1, solder balls SB may be formed on a bottom surface of the substrate SUB, so that the manufacturing of the semiconductor package 100 according to the first example embodiment of the present disclosure may be completed.

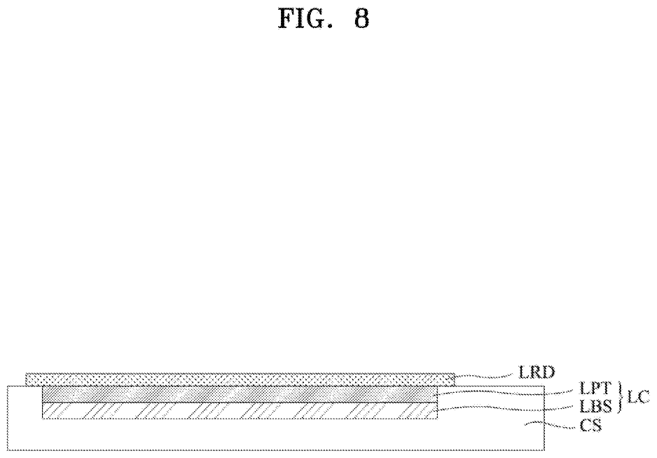

FIGS. 8 to 10 are cross-sectional views illustrating intermediate steps of another method of manufacturing the semiconductor package 100 according to the first example embodiment of the present disclosure.

Referring to FIG. 8, a redistribution layer (e.g., a lower redistribution layer LRD) may be formed on a unit chip (e.g., a lower unit chip LC).

Specifically, a unit chip (e.g., a lower unit chip LC) may be disposed on a carrier substrate CS. For example, the lower unit chip LC may be disposed within the carrier substrate CS such that an active surface of the lower unit chip LC (e.g., a surface of the lower pattern layer LPT) is coplanar with a surface of the carrier substrate CS. Then, a lower redistribution layer LRD may be formed on the lower pattern layer LPT and the surface of the carrier substrate CS.

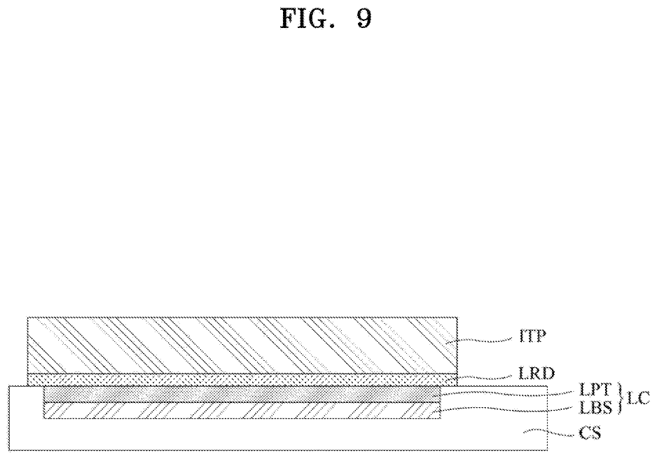

Referring to FIG. 9, an interposer layer ITP may be attached to the lower redistribution layer LRD. For example, a pad on a surface of the interposer layer ITP and a pad on a surface of the lower redistribution layer LRD may be bonded to each other.

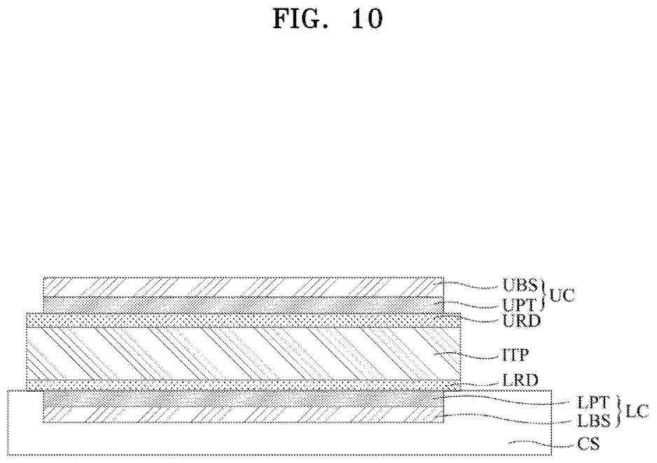

Referring to FIG. 10, an upper redistribution layer URD may be formed on an upper surface of the interposer layer ITP, and an upper unit chip UC may be attached to the upper redistribution layer URD, so that a unit structure (for example, a first unit structure US1) is obtained. The process may be repeated to obtain another unit structure (e.g., a second unit structure US2).

Thereafter, the carrier substrate CS may be removed from the resulting unit structure, and the processes of FIGS. 4 to 7 and FIG. 1 may be performed to complete the manufacturing of the semiconductor package 100 according to the first example embodiment of the present disclosure.

As described above, the method of manufacturing the semiconductor package 100 may eliminate the need for a wire bonding process and a through silicon via process, resulting in a simplified process and an improved yield.

Hereinafter, a semiconductor package according to another example embodiment of the present disclosure and a method of manufacturing the same will be described.

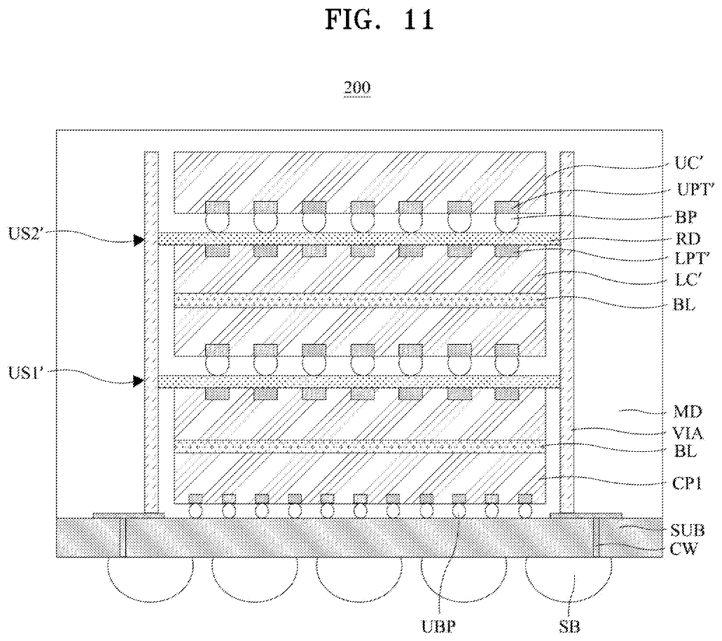

FIG. 11 is a cross-sectional view illustrating a semiconductor package 200 according to a second example embodiment of the present disclosure Referring to FIG. 11, a semiconductor package 200 according to a second example embodiment of the present disclosure includes a substrate SUB, a first chip CP1, a first unit structure US1′, a second unit structure US2′, a molding layer MD, and a conductive via VIA. In FIG. 11, the same reference numerals denote the same or similar elements as those in FIG. 1. Therefore, redundant descriptions will be omitted, and the focus will be on the differences from the first embodiment.

The first chip CP1 may be disposed on a top surface of the substrate SUB. For example, chip pads of the first chip CP1 may be electrically connected to pads on the top surface of the substrate SUB through bottom conductive bumps UBP. The first chip CP1 may be an SoC chip.

The first unit structure US1′ and the second unit structure US2′ may be sequentially stacked on the first chip CP1. As shown in FIG. 11, the first unit structure US1′ may be provided on the first chip CP1, and the second unit structure US2′ may be provided on the first unit structure US1′. For example, the first unit structure US1′ may be bonded to a top surface of the first chip CP1 by an adhesive layer BL, and the second unit structure US2′ may be bonded to the first unit structure US1′ by an adhesive layer BL.

Each of the first unit structure US1′ and the second unit structure US2′ may be a chip structure with a double-sided pattern. For example, each of the first unit structure US1′ and the second unit structure US2′ may include a lower unit chip LC′ and an upper unit chip UC′, and conductive bumps BP and a redistribution layer RD located between the lower unit chip LC′ and the upper unit chip UC′. Each of the lower unit chip LC′ and the upper unit chip UC′ has an active surface and a passive surface opposite to the active surface. The active surfaces of the lower unit chip LC′ and the upper unit chip UC′ may face each other and be electrically connected through the conductive bumps BP and the redistribution layer RD. The redistribution layer RD may make direct contact with the conductive bumps BP.

The passive surface of the upper unit chip UC′ of the first unit structure US1′ and the passive surface of the lower unit chip LC′ of the second unit structure US2′ may face each other and be bonded together by an adhesive layer BL.

The lower unit chip LC′ and the upper unit chip UC′ may be DRAM chips.

Each of the lower unit chip LC′ and the upper unit chip UC′ may include a pattern layer disposed on the active surface. As shown in FIG. 11, the lower unit chip LC′ may include a lower pattern layer LPT′ disposed on the active surface thereof, and the upper unit chip UC′ may include an upper pattern layer UPT′ disposed on the active surface thereof. The lower pattern layer LPT′ and the upper pattern layer UPT′ may face each other.

The conductive bump BP and the redistribution layer RD may be disposed between the lower unit chip LC′ and the upper unit chip UC′. As shown in FIG. 11, the redistribution layer RD is provided on the lower pattern layer LPT′ of the lower unit chip LC′, and the conductive bumps BP are provided on the upper pattern layer UPT′ of the upper unit chip UC′. More specifically, the conductive bumps BP also make direct contact with the upper pattern layer UPT′ of the upper unit chip UC′. In other words, the redistribution layer RD is disposed above the lower unit chip LC′, the conductive bumps BP are disposed above the redistribution layer RD, and the upper unit chip UC′ is disposed above the conductive bumps BP. However, the present disclosure is not limited thereto, and in other embodiments, the conductive bumps BP may be disposed above the lower unit chip LC′, the redistribution layer RD may be disposed above the conductive bumps BP, and the upper unit chip UC′ may be disposed above the redistribution layer RD.

The redistribution layer RD may be electrically connected to the conductive via VIA, enabling electrical connectivity between the lower unit chip LC′ and the conductive via VIA through the redistribution layer RD. Similarly, the upper unit chip UC′ may be electrically connected to the conductive via VIA through the conductive bumps BP and the redistribution layer RD.

The substrate SUB, the conductive via VIA, and the molding layer MD of the semiconductor package 200 of the second example embodiment have structures similar to those of the substrate SUB, the conductive via VIA, and the molding layer MD of the semiconductor package 100 of the first example embodiment, and thus detailed descriptions thereof will be omitted.

Although the semiconductor package 200 is illustrated in FIG. 11 as including only two unit structures, the present disclosure is not limited thereto. The semiconductor package 200 may include one or more additional unit structures stacked on the second unit structure US2′, each having substantially the same structure as the first unit structure US1′ and the second unit structure US2′.

The semiconductor package 200 according to the second example embodiment of the present disclosure includes unit structures configured as a double-sided pattern chip structure, resulting in reduced thickness and enhanced reliability. For example, the semiconductor package 200 may be manufactured without using a wire bonding process or a through silicon via process, and thereby minimizing thickness and improving reliability.

Hereinafter, a method of manufacturing the semiconductor package 200 according to the second example embodiment according to the embodiment of the present disclosure will be described.

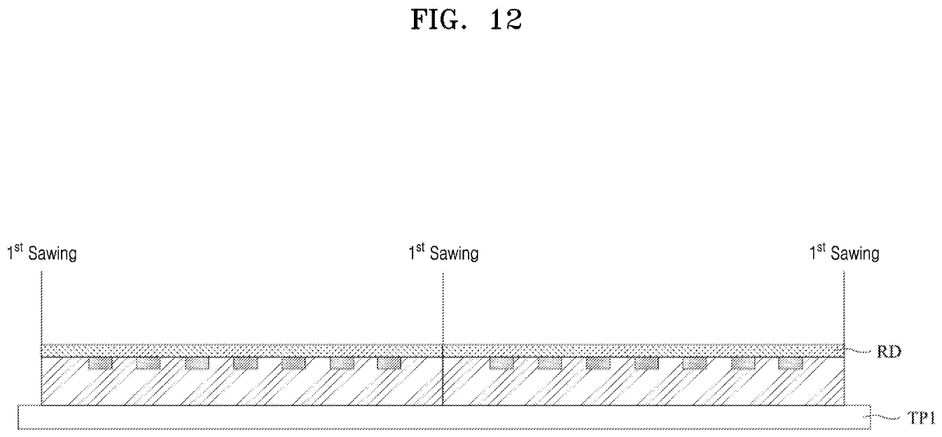

FIGS. 12 to 21 are cross-sectional views illustrating intermediate steps of a method of manufacturing the semiconductor package 200 according to the second example embodiment of the present disclosure.

Referring to FIG. 12, a first sawing may be performed to form a redistribution layer RD.

For example, a surface of a wafer opposite to a surface on which a pattern layer (for example, a lower pattern layer LPT′) is formed may be attached to a first adhesive tape TP1. Subsequently, an initial redistribution layer may be formed on the pattern layer of the wafer. Afterward, a first sawing process may be performed on the initial redistribution layer to form the redistribution layer RD.

For example, two redistribution layers RD are shown in FIG. 12, but the present disclosure is not limited thereto. The number of redistribution layers RD may vary based on the area of the wafer.

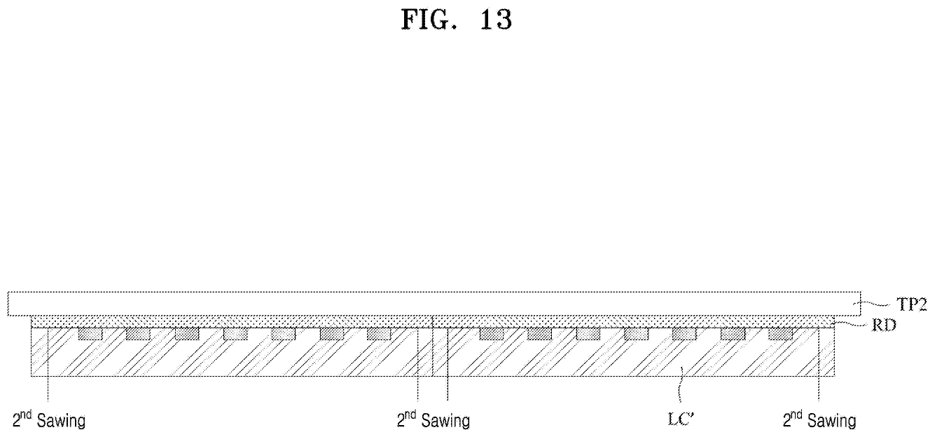

Referring to FIG. 13, a second sawing may be performed to form a unit chip (e.g., a lower unit chip LC′).

For example, as shown in FIG. 13, the first adhesive tape TP1 may be removed, and then a second adhesive tape TP2 may be attached to the redistribution layer RD. The second sawing process may be performed on a surface of the wafer opposite to the surface where the patterned layer is formed, resulting in the formation of a lower unit chip (e.g., lower unit chip LC′). In other example embodiments, the formed unit chip may also serve as an upper unit chip UC.

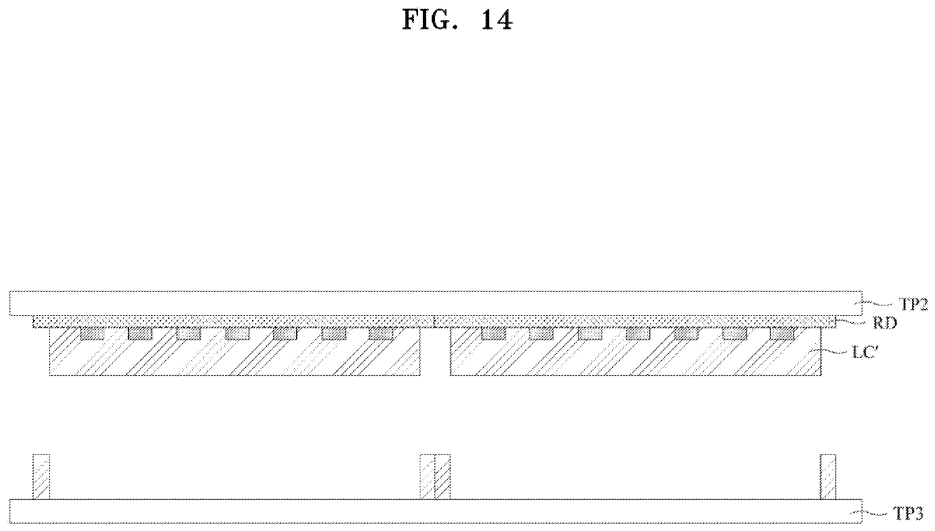

Referring to FIG. 14, the cut-off edge portion of the wafer may be removed.

For example, a third adhesive tape TP3 may be attached to the surface of the wafer opposite to the surface where the pattern layer is formed. The cut-off edge portion of the wafer may then be removed by peeling off the third adhesive tape TP3. Through this process, the redistribution layer RD can protrude from side surfaces of the lower unit chip LC′.

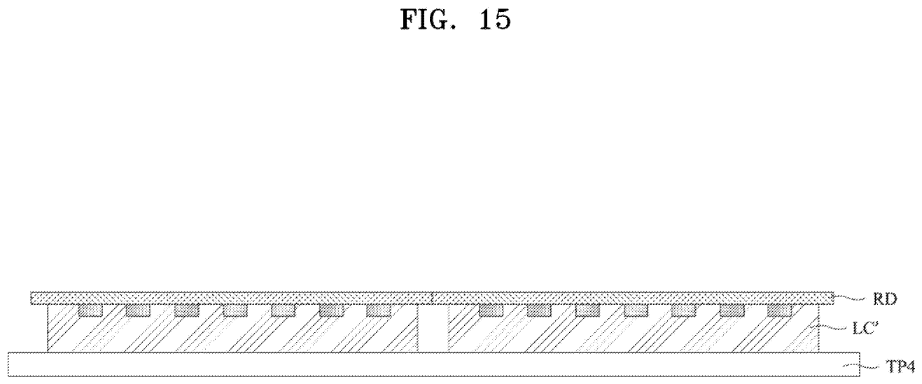

Referring to FIG. 15, the lower unit chip LC′ and the redistribution layer RD may be attached to a fourth adhesive tape TP 4.

For example, the second adhesive tape TP 2 may be removed, and then a passive surface of the lower unit chip LC′ may be attached to the fourth adhesive tape TP 4.

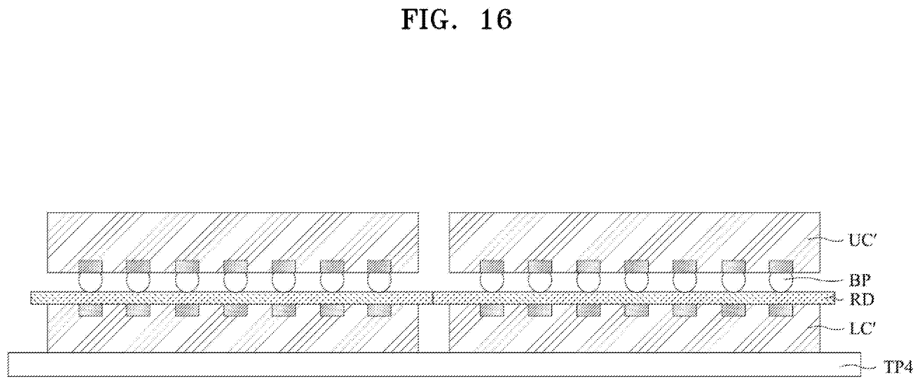

Referring to FIG. 16, a unit structure may be formed.

For example, conductive bumps BP may be formed on an active surface (e.g., the upper pattern layer UPT′) of the upper unit chip UC′. The conductive bumps BP may then be attached to the redistribution layer RD using a chip-to-wafer bonding process, thereby forming a unit structure configured as a double-sided pattern chip structure.

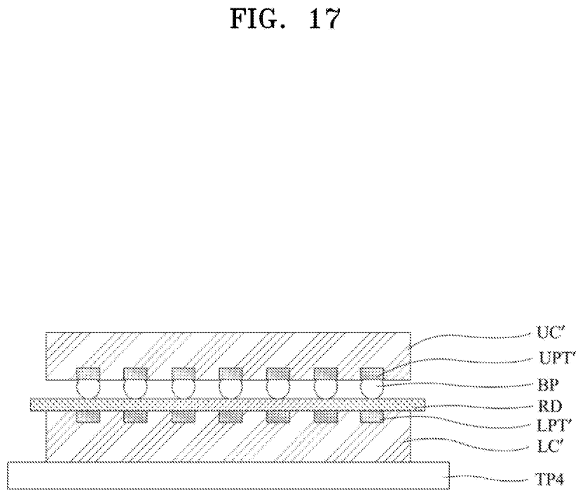

Referring to FIG. 17, the wafer may be sawed to create individual unit structures. The above steps may be repeated to produce multiple unit structures.

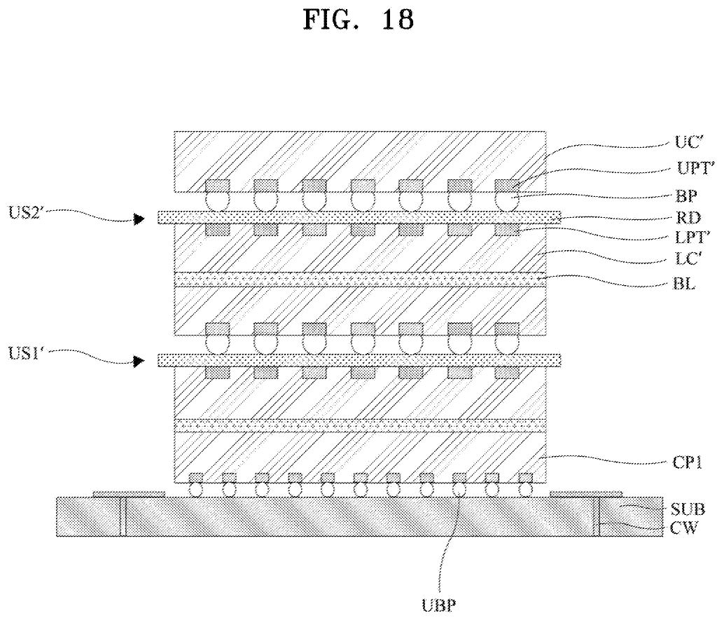

Referring to FIG. 18, a stacked structure of a substrate SUB, a first chip CP1, a first unit structure US1′, and a second unit structure US2′ may be formed.

For example, the first chip CP1 may be attached to the substrate SUB first. Specifically, bottom conductive bumps UBP of the first chip CP 1 may be attached to pads on a top surface of the substrate SUB. Then, the first unit structure US1′ may be attached to a top surface of the first chip CP1 with an adhesive layer BL. Thereafter, the second unit structure US2′ may be attached to the first unit structure US1′ using an adhesive layer BL, ensuring that a passive surface of the upper unit chip UC′ of the first unit structure US1′ and a passive surface of the lower unit chip LC′ of the second unit structure US2′ face each other.

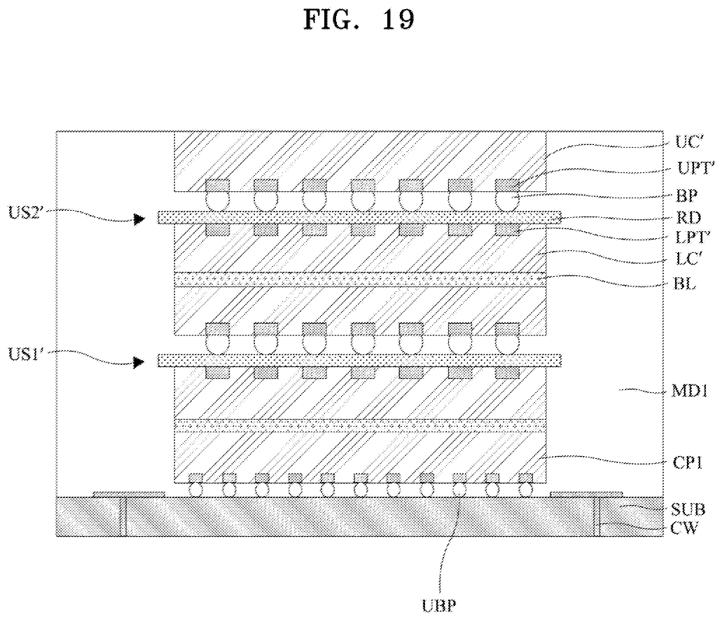

Referring to FIG. 19, a first sub-molding layer MD1 may be formed on the substrate SUB.

For example, a preliminary first sub-molding layer covering the first unit structure US1′ and the second unit structure US2′ may first be formed on the substrate SUB. A planarization process may then be performed on the first sub-molding layer to obtain the first sub-molding layer MD1. The first sub-molding layer MD1 may include or be formed of an epoxy molding compound (EMC). As shown in FIG. 19, a top surface of the first sub-molding layer MD1 may be substantially coplanar with the passive surface of the upper unit chip UC′ of the second unit structure US2′. However, the present disclosure is not limited to this configuration, and the top surface of the first sub-molding layer MD1 may be higher than the passive surface of the upper unit chip UC′ of the second unit structure US2′. For example, the distance from the top surface of the first sub-molding layer MD1 to the top surface of the substrate SUB may be equal to or greater than the distance from the passive surface of the upper unit chip UC of the second unit structure US2′ to the top surface of the substrate SUB.

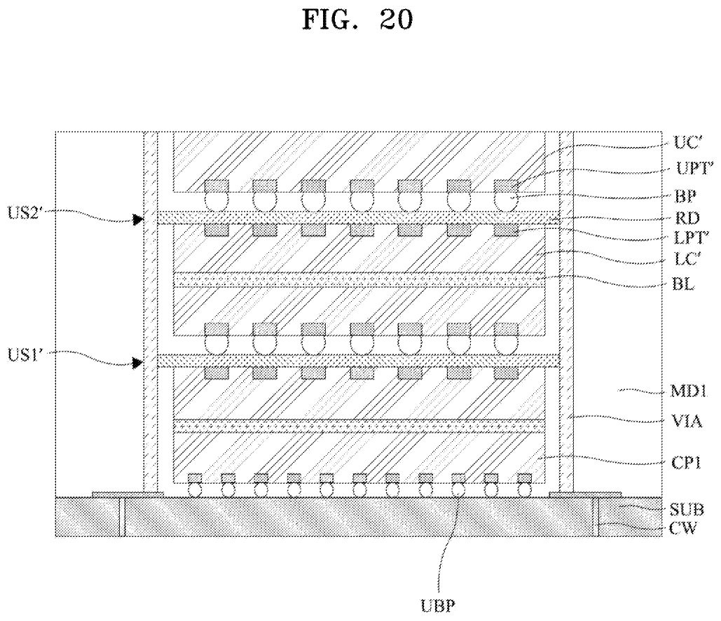

Referring to FIG. 20, conductive vias VIA penetrating the first sub-molding layer MD1 may be formed.

For example, a drilling process may first be performed on the first sub-molding layer MD1 to create through holes that penetrate the first sub-molding layer MD1. The through holes may expose side surfaces of the redistribution layer RD of each of the first unit structure US1′ and the second unit structure US2′. An electroplating process may then be carried out within the through holes to form the conductive vias VIA.

The conductive vias VIA may be electrically connected to a conductive path CW of the substrate SUB, and may also establish electrical connections with the redistribution layer RD of each of the first unit structure US1′ and the second unit structure US2′.

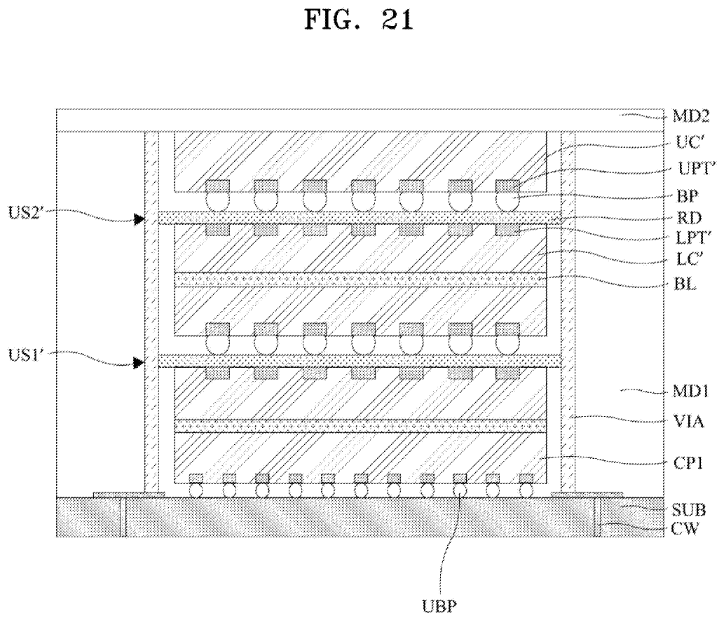

Referring to FIG. 21, a second sub-molding layer MD2 covering the first sub-molding layer MD1, the conductive via VIA, and the passive surface of the upper unit chip UC′ of the second unit structure US2′ may be formed. The second sub-molding layer MD2 may be formed using a process similar to that use for the first sub-molding layer MD1. The second sub-molding layer MD2 may include or be formed of an epoxy molding compound (EMC). A thickness of the second sub-molding layer MD2, referred to as a mold gap, may be relatively small, helping to reduce a thickness of the semiconductor package 100 compared to a package formed using a wire bonding process.

The second sub-molding layer MD2 may include the same material as the first sub-molding layer MD1. The first sub-molding layer MD1 and the second sub-molding layer MD2 may constitute the molding layer MD.

Next, referring to FIG. 11, solder balls SB may be formed on a bottom surface of the substrate SUB, so that the manufacturing of the semiconductor package 200 according to the second example embodiment of the present disclosure may be completed.

As described above, the method of manufacturing the semiconductor package 200 may eliminate the need for a wire bonding process and a through-silicon via process. As a result, the semiconductor package 200 benefits from a simplified manufacturing process and improved yield.

Hereinafter, a semiconductor package and a manufacturing method thereof according to still another example embodiment of the present disclosure will be described.

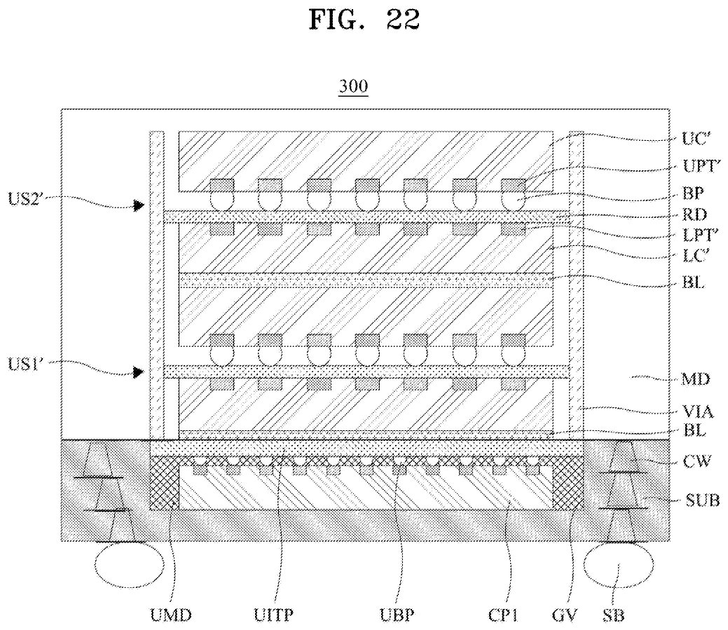

FIG. 22 is a cross-sectional view illustrating a semiconductor package 300 according to a third example embodiment of the present disclosure.

Referring to FIG. 22, a semiconductor package 300 according to a third example embodiment of the present disclosure includes a substrate SUB, a first chip CP1, a bottom interposer layer UITP, a first unit structure US1′, a second unit structure US2′, a molding layer MD, and a conductive via VIA. In FIG. 22, the same reference numerals denote the same or similar elements as those in FIG. 11. Therefore, redundant descriptions will be omitted, and the focus will be on the differences from the second embodiment.

The substrate SUB may have a groove GV. For example, the groove GV may be located on a top surface of the substrate SUB.

The first chip CP1 may be provided in the groove GV of the substrate SUB. In other words, the first chip CP1 may be disposed within the substrate SUB. A passive surface of the first chip CP1 may face a bottom surface of the substrate SUB, and an active surface of the first chip CP1 may face the opening side of the groove GV or a top surface of the substrate SUB. The first chip CP1 may be an SoC chip.

The first chip CP1 may be covered by a bottom molding layer UMD. For example, the bottom molding layer UMD may fill a portion of the groove GV of the substrate SUB. More specifically, the bottom molding layer UMD may fill a portion of the groove GV that is located between the first chip CP1 and the substrate SUB.

The bottom interposer layer UITP may be located above the first chip CP1. For example, the bottom interposer layer UITP may be located above the bottom molding layer UMD and electrically connected to a chip pad of the first chip CP1 through bottom conductive bumps UBP. A top surface of the bottom interposer layer UITP may be substantially coplanar with the top surface of the substrate SUB. The bottom interposer layer UITP may overlap the groove GV such that it covers the bottom molding layer UMD.

The first unit structure US1′ and the second unit structure US2′ may be sequentially stacked on the first chip CP1. As shown in FIG. 22, the first unit structure US1′ may be provided on the bottom interposer layer UITP, and the second unit structure US2′ may be provided on the first unit structure US1′. For example, the first unit structure US1′ may be bonded to the bottom interposer layer UITP by an adhesive layer BL, and the second unit structure US2′ may be bonded to the first unit structure US1′ by an adhesive layer BL.

The first unit structure US1′ and the second unit structure US2′ of the semiconductor package 300 according to the third example embodiment of the present disclosure may have substantially the same structure as the first unit structure US1′ and the second unit structure US2′ of the semiconductor package 200 illustrated in FIG. 11. Therefore, their description will not be repeated here.

The substrate SUB, the conductive via VIA, and the molding layer MD of the semiconductor package 300 according to the third embodiment of the present disclosure may have a structure similar to those of the substrate SUB, the conductive via VIA, and the molding layer MD of the semiconductor package 100 of the first embodiment and the semiconductor package 200 of the second embodiment. Therefore, a detailed description will be omitted.

Although the semiconductor package 300 is illustrated in FIG. 22 as including only two unit structures, the present disclosure is not limited to this configuration. The semiconductor package 300 may include one or more additional unit structures stacked on the second unit structure US2′, each having substantially the same structure as the first unit structure US1′ and the second unit structure US2′.

The semiconductor package 300 according to the third example embodiment of the present disclosure includes unit structures configured as a double-sided pattern chip structure, resulting in reduced thickness and enhanced reliability. For example, the semiconductor package 300 may be manufactured without using a wire bonding process or a through silicon via process, thereby minimizing thickness and reducing reliability.

In addition, since the first chip CP1 of the semiconductor package 300 according to the third example embodiment of the present disclosure is provided in the groove GV of the substrate SUB, the overall thickness of the semiconductor package 300 can be further reduced.

Hereinafter, a method of manufacturing the semiconductor package 300 according to the third example embodiment according to the embodiment of the present disclosure will be described.

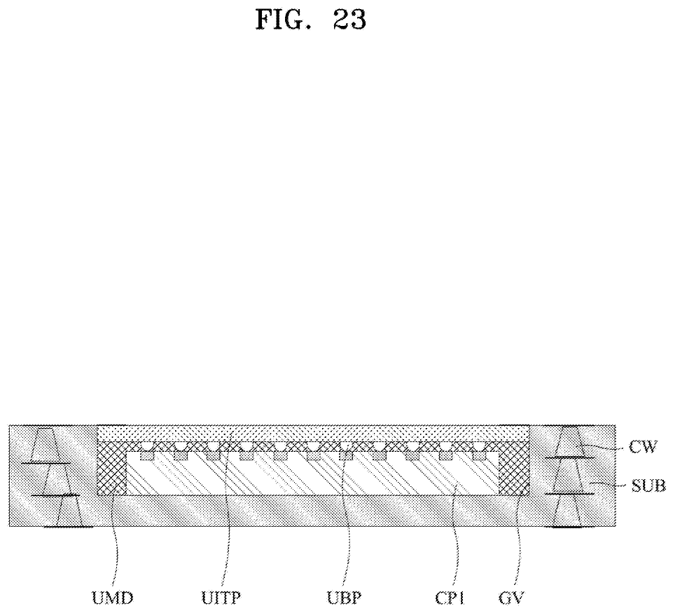

FIGS. 23 to 27 are cross-sectional views illustrating intermediate steps of a method of manufacturing the semiconductor package 300 according to the third example embodiment of the present disclosure.

First, referring to FIGS. 12 to 17, a plurality of unit structures may be prepared using substantially the same steps as those employed in manufacturing the semiconductor package 200 according to the second example embodiment of the present disclosure.

Next, referring to FIG. 23, a substrate SUB having a groove GV may be prepared, and a first chip CP1 may be placed in the groove GV of the substrate SUB such that an active surface of the first chip CP1 faces an opening side of the groove GV (e.g., the upper open side of the groove GV). Then, bottom conductive bumps UBP may be formed on a chip pad of the first chip CP1, and a bottom interposer layer UITP may be bonded to the first chip CP1 through the bottom conductive bump UBP, ensuring that a top surface of the bottom interposer layer UITP is substantially coplanar with a top surface of the substrate SUB. Thereafter, a sealing material such as an epoxy molding compound (EMC) may be filled into the groove GV, forming a bottom molding layer UMD that covers the first chip CP1.

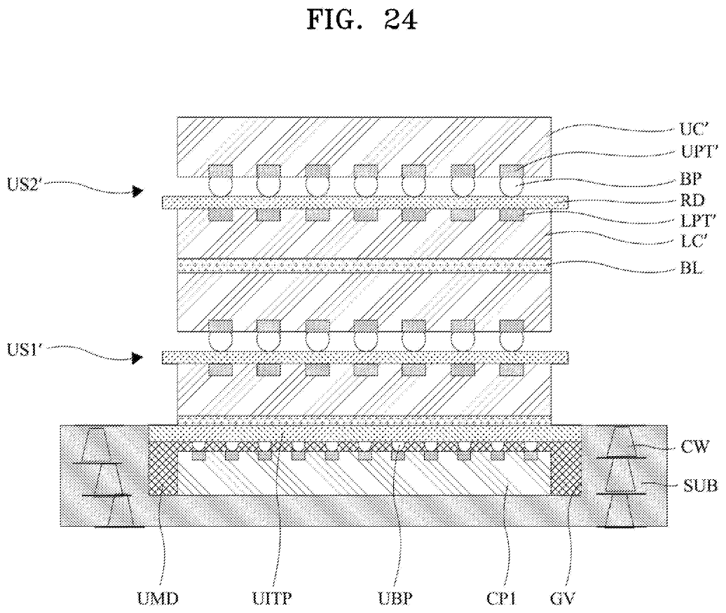

Referring to FIG. 24, a stacked structure of the first chip CP1, a first unit structure US1′, and a second unit structure US2′ may be formed.

For example, the first unit structure US1′ may be attached to the top surface of the bottom interposer layer UITP with an adhesive layer BL. Thereafter, the second unit structure US2′ may be attached to the first unit structure US1′ with an adhesive layer BL, ensuring that a passive surface of an upper unit chip UC′ of the first unit structure US1′ and a passive surface of a lower unit chip LC′ of the second unit structure US2′ face each other.

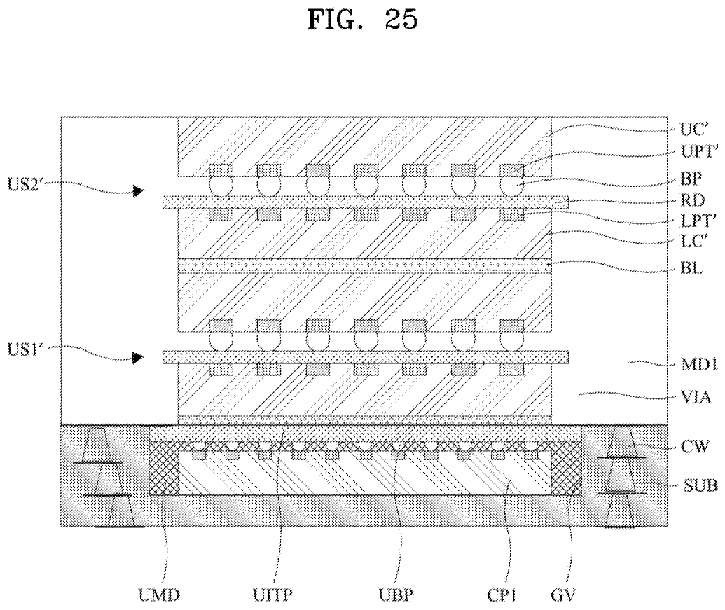

Referring to FIG. 25, a first sub-molding layer MD1 may be formed on the substrate SUB.

For example, a preliminary first sub-molding layer covering the first unit structure US1′ and the second unit structure US2′ may be formed on the substrate SUB first. Then, a planarization process may be performed on the first sub-molding layer to obtain the first sub-molding layer MD1. The first sub-molding layer MD1 may include or be formed of an epoxy molding compound (EMC). As shown in FIG. 25, a top surface of the first sub-molding layer MD1 may be substantially coplanar with the passive surface of the upper unit chip UC′ of the second unit structure US2′. However, the present disclosure is not limited thereto, and the top surface of the first sub-molding layer MD1 may be higher than the passive surface of the upper unit chip UC′ of the second unit structure US2′. For example, the distance from the top surface of the first sub-molding layer MD1 to the top surface of the substrate SUB may be equal to or greater than the distance from the passive surface of the upper unit chip UC of the second unit structure US2′ to the top surface of the substrate SUB.

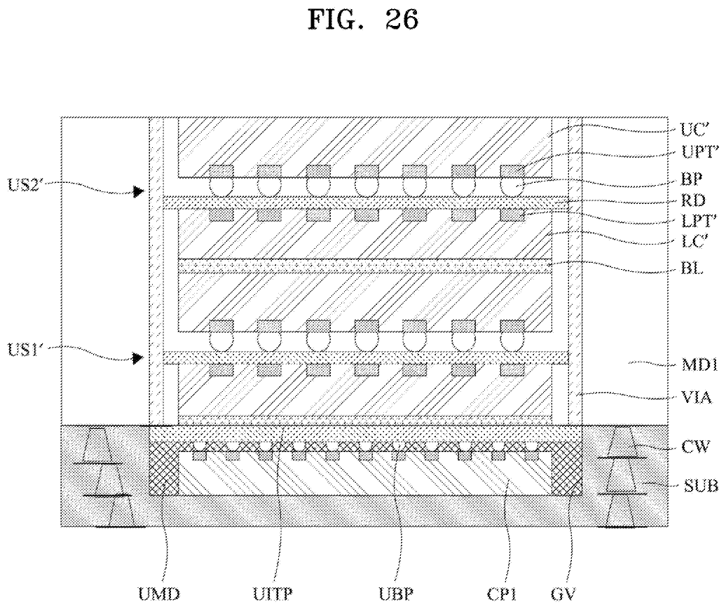

Referring to FIG. 26, conductive vias VIA penetrating the first sub-molding layer MD1 may be formed.

For example, a drilling process may first be performed on the first sub-molding layer MD1 to form through holes that penetrate the first sub-molding layer MD1. The through holes may expose side surfaces of the redistribution layer RD of each of the first unit structure US1′ and the second unit structure US2′. An electroplating process may then be performed on the through holes to form the conductive via VIA.

The conductive via VIA may be electrically connected to a conductive path CW of the substrate SUB, and may be electrically connected to the redistribution layer RD of each of the first unit structure US1′ and the second unit structure US2′.

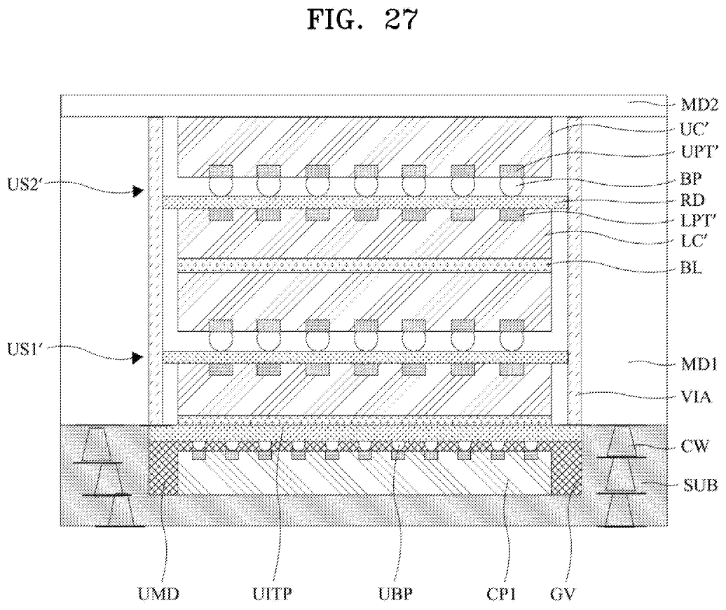

Referring to FIG. 27, a second sub-molding layer MD2 covering the first sub-molding layer MD1, the conductive via VIA, and the passive surface of the upper unit chip UC′ of the second unit structure US2′ may be formed. The second sub-molding layer MD2 may be formed by substantially the same process as the process of forming the first sub-molding layer MD1. The second sub-molding layer MD2 may include or be formed of an epoxy molding compound (EMC). A thickness of the second sub-molding layer MD2 may be referred to as a mold gap. The second sub-molding layer MD2 may have a relatively small thickness, helping to reduce a thickness of the semiconductor package 100 compared to a package formed using a wire bonding process.

The second sub-molding layer MD2 may include the same material as the first sub-molding layer MD1. The first sub-molding layer MD1 and the second sub-molding layer MD2 may constitute the molding layer MD.

Next, referring to FIG. 22, solder balls SB may be formed on a bottom surface of the substrate SUB, completing the manufacturing of the semiconductor package 300 according to the third example embodiment of the present disclosure.

As described above, the method of manufacturing the semiconductor package 300, eliminates the need for a wire bonding process and a through silicon via process may not be used, resulting in a simplified manufacturing process and improved yield. In addition, since the first chip CP1 is positioned within the groove GV of the substrate SUB, the overall thickness of the semiconductor package 300 can be further reduced.

The semiconductor package according to an example embodiment of the present disclosure includes unit structures configured as a double-sided pattern chip structure. This design enables a reduced thickness, enhanced reliability, and improved electrical performance.

Although the present disclosure has been specifically shown and described with reference to some example embodiments thereof, it will be understood that various changes in form and detail may be made without departing from the spirit and scope of the appended claims.

1. A semiconductor package, comprising:
a substrate;
a first unit structure and a second unit structure sequentially stacked on the substrate;
a molding layer on the substrate and covering the first unit structure and the second unit structure; and
a conductive via within the molding layer and electrically connected to the substrate,
wherein each of the first unit structure and the second unit structure comprises: an interposer layer; a lower unit chip below the interposer layer; an upper unit chip above the interposer layer; a lower redistribution layer between the lower unit chip and the interposer layer and electrically connected to the interposer layer, the lower unit chip, and the conductive via; an upper redistribution layer between the upper unit chip and the interposer layer and electrically connected to the interposer layer, the upper unit chip and the conductive via,
wherein each of the lower unit chip and the upper unit chip has an active surface facing the interposer layer and a passive surface opposite to its active surface, and
wherein the passive surface of the upper unit chip of the first unit structure and the passive surface of the lower unit chip of the second unit structure face each other.

2. The semiconductor package of claim 1, wherein the lower unit chip comprises a lower base layer and a lower pattern layer between the lower base layer and the lower redistribution layer, the lower pattern layer being electrically connected to the lower redistribution layer, and
wherein the upper unit chip comprises an upper base layer and an upper pattern layer between the upper base layer and the upper redistribution layer, the upper pattern layer being electrically connected to the upper redistribution layer.

3. The semiconductor package of claim 1, further comprising an adhesive layer between the first unit structure and the second unit structure.

4. The semiconductor package of claim 1, wherein the molding layer comprises a first sub-molding layer and a second sub-molding layer,
wherein the conductive via penetrates the first sub-molding layer, and
wherein the second sub-molding layer covers the first sub-molding layer and the conductive via.

5. The semiconductor package of claim 4, wherein a distance from a top surface of the first sub-molding layer to a top surface of the substrate is equal to or greater than a distance from the passive surface of the upper unit chip to the second unit structure from the top surface of the substrate.

6. The semiconductor package of claim 1, wherein a side surface of the interposer layer, a side surface of the lower redistribution layer, and a side surface of the upper redistribution layer are in contact with the conductive via, and
wherein a side surface of the lower unit chip and a side surface of the upper unit chip are spaced apart from the conductive via.

7. The semiconductor package of claim 2, wherein the interposer layer has a first width,
wherein the lower and upper redistribution layers have a second width,
wherein the lower and upper pattern layers have a third width,
wherein the lower and upper base layers have a fourth width,
wherein the first width is equal to the second width,
wherein the third width is equal to the fourth width, and
wherein the first width is greater than the third width.

8. The semiconductor package of claim 1, further comprising a third unit structure above the second unit structure, and
wherein the third unit structures has a same structure as the first unit structure and the second unit structure.

9. A semiconductor package, comprising:
a substrate;
a first chip in a groove of the substrate;
a first unit structure above the first chip;
a second unit structure above the first unit structure;
a molding layer on the substrate and covering the first unit structure and the second unit structure; and
a conductive via within the molding layer and electrically connected to the substrate,
wherein each of the first unit structure and the second unit structure comprises: a lower unit chip and an upper unit chip each comprising an active surface and a passive surface opposite to its active surface; a conductive bump between the lower unit chip and the upper unit chip and directly connected to one of the lower unit chip and the upper unit chip; and a redistribution layer between the lower unit chip and the upper unit chip and directly connected to the conductive bump and conductive via and the other one of the lower unit chip and the upper unit chip,
wherein in each of the lower unit chip and the upper unit chip, the active surface of the lower unit chip and the active surface of the upper unit chip face each other, and
wherein the passive surface of the upper unit chip of the first unit structure and the passive surface of the lower unit chip of the second unit structure face each other.

10. The semiconductor package of claim 9, wherein the redistribution layer is between the lower unit chip and the conductive bump, and
wherein the conductive bump is between the upper unit chip and the redistribution layer.

11. The semiconductor package of claim 9, wherein the conductive bump is between the lower unit chip and the redistribution layer, and
wherein the redistribution layer is between the upper unit chip and the conductive bump.

12. The semiconductor package of claim 9, further comprising an adhesive layer between the first unit structure and the second unit structure.

13. The semiconductor package of claim 9, wherein the molding layer comprises a first sub-molding layer and a second sub-molding layer,
wherein the conductive via penetrates the first sub-molding layer, and
wherein the second sub-molding layer covers the first sub-molding layer and the conductive via.

14. The semiconductor package of claim 13, wherein a distance from a top surface of the first sub-molding layer to a top surface of the substrate is equal to or greater than a distance from the passive surface of the upper unit chip to the second unit structure from the top surface of the substrate.

15. The semiconductor package of claim 9, wherein a side surface of the redistribution layer is in contact with the conductive via, and
wherein a side surface of the lower unit chip and a side surface of the upper unit chip are spaced apart from the conductive via.

16. The semiconductor package of claim 9, wherein the redistribution layer has a first width,
wherein the lower unit chip and the upper unit chip have a second width, and
wherein the first width is greater than the second width.

17. The semiconductor package of claim 9, further comprising a third unit structure above the second unit structure, and
wherein the unit structure has a same structure as the first unit structure and the second unit structure.

18. The semiconductor package of claim 9, wherein the first chip is on an upper surface of the substrate and is electrically connected to the substrate through a bottom conductive bump, and
wherein the first unit structure is attached to the first chip by an adhesive layer.

19. The semiconductor package of claim 9, wherein the first chip is in the groove of the substrate,
wherein the semiconductor package further comprises a bottom interposer layer above the first chip within the groove of the substrate,
wherein the bottom interposer layer is electrically connected to the first chip through a bottom conductive bump, and
wherein the first unit structure is attached to the bottom interposer layer by an adhesive layer.

20-33. (canceled)
